(19) United States
(12) Patent Application Publication
(10) Pub. No.: US 2025/0104981 A1
(43) Pub. Date: Mar. 27, 2025

(54) PLASMA PROCESSING METHOD

(71) Applicant: Hitachi High-Tech Corporation, Minato-ku, Tokyo (JP)

(72) Inventors: Kosa HIROTA, Tokyo (JP); Masahiro SUMIYA, Tokyo (JP); Ryu EZAKI, Tokyo (JP); Anil PANDEY, Tokyo (JP); Yuki MORIYA, Tokyo (JP)

(21) Appl. No.: 18/279,818

(22) PCT Filed: Jun. 8, 2022
(86) PCT No.: PCT/JP2022/023040

§ 371 Date: Aug. 31, 2023

(51) Int. Cl. H01J 37/32

(52) U.S. Cl. CPC H01J 37/32853; H01J 37/32449; H01J 37/3288; H01J 2237/334

(57) ABSTRACT

Provided is a plasma processing method for implementing a state in which product manufacturing can be started in a short period of time by reducing particles generated after maintenance of a plasma processing apparatus. The plasma processing method for plasma-processing a sample includes: a sweeping step of sweeping out a particle after maintenance of a processing chamber in which the sample is plasma-processed; a deposition step of depositing a deposition film in the processing chamber after the sweeping step; a first removing step of removing the deposition film after the deposition step; a second removing step of removing fluorine in the processing chamber after the first removing step; and a plasma processing step of plasma-processing the sample placed on a sample stage. The sweeping step, the deposition step, the first removing step, and the second removing step are repeated two or more times before the plasma processing step.

### TECHNICAL FIELD

The present disclosure relates to a technique for reducing particles in a processing chamber in a short period of time, which cause a decrease in the yield of a product wafer in a plasma etching processing apparatus for processing a wafer such as a semiconductor substrate, and in particular, an object of the present disclosure is to provide a plasma processing method for implementing a state in which product manufacturing can be started in a short period of time by previously reducing particles generated after maintenance of a plasma etching apparatus.

### BACKGROUND ART

In a plasma etching apparatus for processing a semiconductor, the reduction for a management particle size of a particle which causes a decrease in the yield of a semiconductor device and an allowable number thereof are increasingly strict year by year. Since the decrease in the yield due to the particle has a critical influence on a profit of a semiconductor device manufacturer, a manufacturer of the plasma etching apparatus is strongly required to design and manufacture a plasma etching apparatus having a high yield and a high operation rate.

In order to implement reduction of the particles, various attempts are made on both a hardware aspect and a process aspect. In the process aspect, a cleaning technique for etch byproducts generated in an etching processing is developed, and in the hardware aspect, for example, a processing chamber member is developed, a component cleaning technique is optimized, a processing chamber structure is optimized, a replacement component range in the processing chamber is optimized. The technique development and the optimization are progressing day by day. Although these development efforts are made, in general, in a plasma etching processing in a mass production processing of the semiconductor device, as the number of products to be processed (the number of semiconductor wafers to be processed) increases, the performance of the particle and processing reproducibility decreases due to deterioration of members used in the plasma etching apparatus, etch byproducts generated in a product processing (semiconductor wafer processing), and the like. Therefore, the mass production processing may not be continued.

In response to such a problem, the plasma etching apparatus recovers the performance of the particle and the processing reproducibility by a periodic maintenance work with parts replacement. After the maintenance work, vacuuming is continued until a vacuum leak amount reaches a specified value, and thereafter, a recovery processing using a plasma process or the like is performed to reduce the number of particles, and then product manufacturing is started. However, even when the plasma process or the like is used, there is a movable portion related to wafer transfer or wafer processing in the processing chamber of the plasma etching apparatus, and it is necessary to sufficiently reduce particle sources caused by an operation of the movable portion.

Therefore, in the recovery processing, it is necessary to start manufacturing a product by paying attention to reducing potential particle sources in addition to a seasoning sense for adjusting a surface state of an inner wall of the processing chamber. In addition, since the recovery processing does not contribute to the product processing, the recovery processing is one cause of a decrease in operation rate. Therefore, the present inventors considered that a new technique focusing on the movable portion related to wafer transfer or wafer processing is required as a technique for quickly reducing the number of particles after maintenance (referred to as the initial number of particles) to a set reference value (the number of particles as the set reference value) or less.

As a typical related art for the purpose of reducing particles, there is disclosed a technique of exhausting gas immediately before etching of a product wafer to reduce particles on the product wafer (PTL 1). In addition, as a technique of reducing process processing variation, there is disclosed a technique of forming a coating film on a processing wall for each processing of a product wafer (PTL 2).

### CITATION LIST

### Patent Literature

PTL 1: JP-2006-210461A
PTL 2: U.S. Pat. No. 7,767,584B

### SUMMARY OF INVENTION

### Technical Problem

The reduction of the management particle size of the particle which causes the decrease in the yield of the semiconductor device and the allowable number thereof are increasingly strict year by year, and in order to quickly reduce the number of particles after maintenance (referred to as the initial number of particles) to the set reference value or less, it is necessary to sufficiently reduce the potential particle sources caused by the movable portion related to wafer transfer or wafer processing. Examples of the operation of the movable portion include an operation of raising and lowering a vertical mechanism of a pusher pin, an operation of opening and closing an inlet and outlet valve for wafer transfer, an operation of opening and closing an electromagnetic valve of a gas introduction portion, and an operation of opening and closing an exhaust valve. Regarding the particle generated in this way, it is difficult to satisfy a fairly severe management standard for the particle in the future in a recovery processing in the related art.

Focusing on these problems, an object of the present disclosure is to provide a plasma processing method for implementing a state in which product manufacturing can be started by reducing particles generated after maintenance of a plasma processing apparatus. Other problems and novel features will become apparent from the description of the present description and the accompanying drawings.

### Solution to Problem

An overview of a representative aspect of the present disclosure will be briefly described as follows.

A plasma processing method according to an embodiment is a plasma processing method for plasma-processing a sample. The plasma processing method includes: a sweeping step of sweeping out a particle after maintenance of a processing chamber in which the sample is plasma-processed; a deposition step of depositing a deposition film in the processing chamber after the sweeping step; a first removing step of removing the deposition film after the deposition step; a second removing step of removing fluorine in the processing chamber after the first removing step; and a plasma processing step of plasma-processing the sample placed on a sample stage. The sweeping step, the deposition step, the first removing step, and the second removing step are repeated two or more times before the plasma processing step.

### Advantageous Effects of Invention

According to the plasma processing method of the above embodiment, the particle is swept by various mechanical operations in the sweeping step, and the particle swept in the sweeping step is quickly removed by the subsequent deposition step, first removing step, and second removing step. Accordingly, a plasma processing apparatus can be implemented in a state in which product manufacturing can be started in a short period of time. In addition to the implementation of the plasma processing apparatus, it is possible to previously reduce potential particle sources generated after the product processing, and it is possible to stably continue a mass production processing of plasma etching.

### BRIEF DESCRIPTION OF DRAWINGS

FIG. 1 is a cross-sectional view illustrating a schematic configuration of a microwave ECR etching apparatus according to Embodiment 1.

FIG. 2 is a flowchart illustrating a first sequence according to Embodiment 1.

FIG. 3A is a diagram illustrating a relation between the number of times of a recovery processing and the number of particles.

FIG. 3B is a schematic diagram illustrating an estimation mechanism for removing a particle according to Embodiment 2.

FIG. 4 is a flowchart illustrating a particle sweeping confirmation sequence.

FIG. 5 is a table illustrating test contents of the particle sweeping confirmation sequence.

FIG. 6 is an evaluation result diagram illustrating correspondence between an evaluation No. and the number of particles in a particle sweeping sequence.

FIG. 7 is a flowchart illustrating a second sequence according to Embodiment 2.

FIG. 8 is a diagram illustrating the number of reached particles when processed using the second sequence and a second' sequence.

FIG. 9 is a diagram illustrating results of the number of particles obtained by acquiring a time dependence of a coating step processing using the second sequence.

### DESCRIPTION OF EMBODIMENTS

Hereinafter, embodiments will be described with reference to the drawings. In the following description, the same components may be denoted by the same reference numerals, and repeated descriptions may be omitted. In order to make the description clearer, the drawings may be schematically represented as compared with actual aspects, and they are merely examples and do not limit the interpretation of the present disclosure.

### Embodiment 1

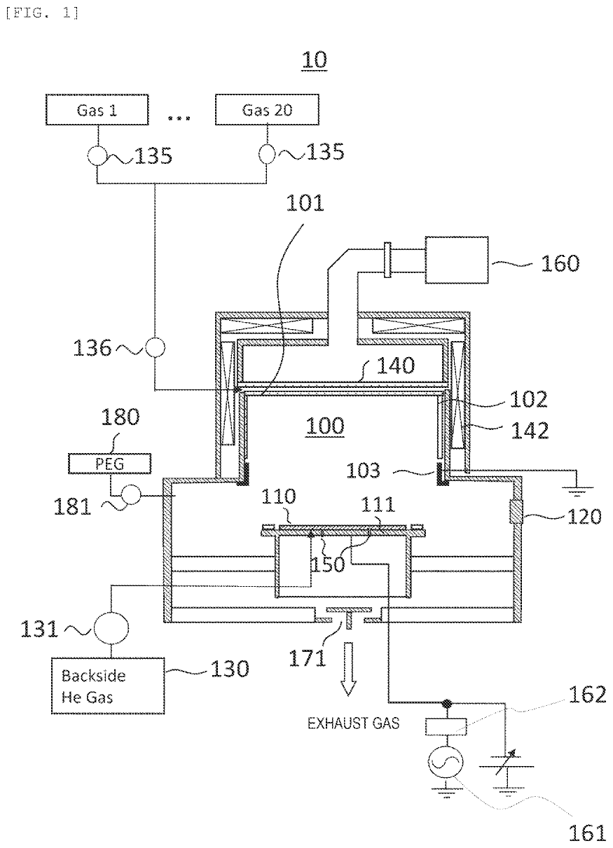

Embodiment 1 will be described. FIG. 1 is a cross-sectional view illustrating a schematic configuration of a microwave ECR etching apparatus according to Embodiment 1. As an example of a plasma processing apparatus applied to the present disclosure, a microwave ECR etching apparatus (hereinafter referred to as a plasma etching apparatus) 10 illustrated in FIG. 1 may be used. The plasma etching apparatus 10 includes an electrode (wafer placement electrode) 111 on which a wafer 110 is placed in a processing container (also referred to as a processing chamber or a chamber) 100, a process valve (PV) 120 serving as an inlet and outlet for supplying the wafer 110 between the processing chamber 100 and a transfer unit (not illustrated), electromagnetic valves 135 for gas supply devices, an electromagnetic valve 136 that controls gas supply, a top plate 140, a quartz shower plate 101, and a quartz inner tube 102. The electrode (wafer placement electrode) 111 is a sample stage on which the wafer 110 as a sample is placed.

The plasma etching apparatus 10 further includes a ground 103, an electromagnet 142, a radio frequency generator and a radio frequency waveguide 160 that generate and transmit microwaves for generating a plasma, an RF bias power source 161, a matching device 162, a vacuum exhaust valve 171 that controls a pressure in the processing chamber 100, a Penning gauge 180 that measures a degree of vacuum in the processing chamber 100, and an electromagnetic valve 181 that controls cutout between the Penning gauge 180 and the chamber 100. The plasma etching apparatus 10 further includes a backside gas supply device 130 that supplies a backside gas as a heat medium for the wafer 110 and the electrode 111, an electromagnetic valve 131 that controls the supply of the backside gas, and a pusher pin 150, which is a mechanism for raising and lowering the wafer 110 in order to transfer the wafer 110 to a transfer robot during wafer transfer.

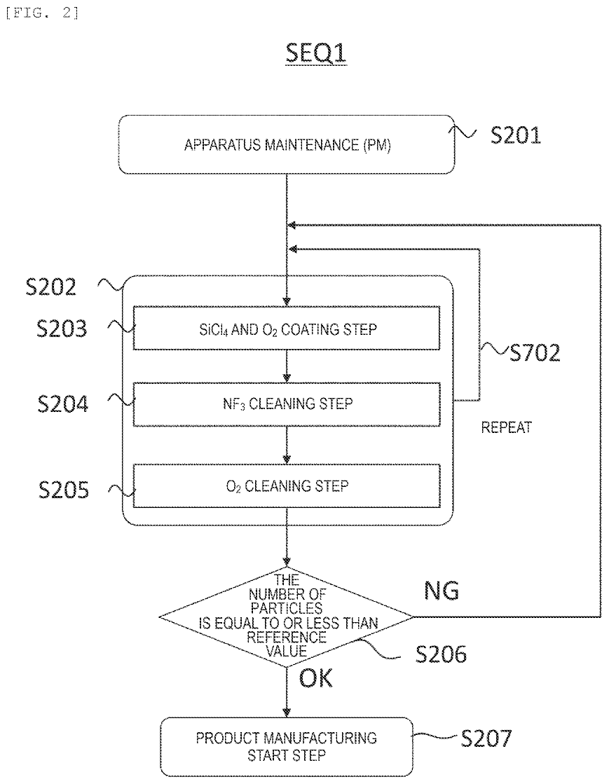

FIG. 2 is a flowchart illustrating a first sequence (SEQ1) according to Embodiment 1. The first sequence (SEQ1) can be referred to as a plasma processing method performed by the plasma etching processing apparatus 10 that manufactures a product after reducing potential particle sources in a processing chamber.

As described in the present background, in a mass production processing of the plasma etching apparatus 10, the mass production processing cannot be continued due to an amount of consumption of members constituting the processing chamber 100, deterioration of components, and the like. In order to recover the mass production processing, the plasma etching apparatus 10 requires apparatus maintenance (PM) S201 with periodic atmospheric opening. After the work of the apparatus maintenance S201, vacuum leak is checked and vacuuming is continued until a leak amount reaches a specified value. After the leak check is completed, a recovery processing S202 is repeatedly performed until the initial number of particles is equal to or less than a reference value (S206, NG) (S702). When the recovery processing S202 is sufficient and the number of particles is equal to or less than the reference value (S206, OK), a product manufacturing start step S207 is enabled and is performed. The product manufacturing start step S207 can be referred to as a plasma processing step of plasma-processing the sample 110 placed on the sample stage 111.

It takes a long time to confirm whether the initial number of particles is equal to or less than the reference value (S206: confirming the number of particles), and thus it takes a long time to confirm the number of particles (S206) each time after the recovery processing S202 is performed once, which is not efficient. Therefore, it is preferred to confirm the number of particles (S206) in a short period of time after the recovery processing S202 is repeatedly performed a predetermined number of times (S702).

In the present embodiment, the recovery processing S202 includes three steps, that is, a SiCl₄ and O₂ coating step S203, an NF₃ cleaning step S204, and an O₂ cleaning step S205, and is repeated a plurality of times (for example, about 12 times) in this order (S203->S204->S205) (S702).

Processing conditions of the SiClₐ and O₂ coating step S203 were, for example, SiCl₄=100 ccm, O₂=100 ccm, a pressure of 0.5 Pa, a microwave power of 600 w, and 15 seconds. Processing conditions of the NF₃ cleaning step S204 were, for example, NE₃=500 ccm, a pressure of 15 Pa, a microwave power of 1000 w, and 45 seconds. Processing conditions of the O₂ cleaning step S205 were, for example, O₂=100 ccm, a pressure of 0.4 Pa, a microwave power of 600 w, and 30 seconds.

In the recovery processing S202, a SiOₓ coating film on a surface of an inner wall surface of the processing chamber 100 generated in the SiCl₄ and O₂ coating step S203 is completely removed in the next NF₃ cleaning step S204, and residual fluorine generated in the NF₃ cleaning step S204 is completely removed in the next O₂ cleaning step S205.

That is, the SiCl₄ and O₂ coating step S203 is a processing step of performing a plasma processing using a gas containing Si and O (SiCl₄ gas and O₂ gas), and the SiOₓ coating film is generated on the surface of the wall surface of the processing chamber 100 in the processing step (S203). Therefore, the processing step (S203) can be referred to as a deposition step of depositing a deposition film which is the SiOₓ coating film in the processing chamber 100. In addition, the deposition step (S203) is performed using a plasma generated by a gas containing a silicon element. The gas containing the silicon element is SiCl₄ gas.

The NF₃ cleaning step S204 is a first removing step of removing, with NF₃ gas, the SiOₓ coating film on the surface of the wall surface of the processing chamber 100 generated in the processing step (S203). Therefore, the NF₃ cleaning step S204 can be referred to as the first removing step for removing the deposition film (SiOₓ coating film), which is performed after the deposition step (S203). The first removing step (S204) is performed using a plasma generated by the NF₃ gas.

The O₂ cleaning step S205 is a second removing step of removing, with the O₂ gas, the residual fluorine on the surface of the wall surface of the processing chamber 100 generated in the first removing step (S204). Therefore, the O₂ cleaning step S205 can be referred to as the second removing step of removing fluorine in the processing chamber 100, which is performed after the first removing step (S204). The second removing step (S205) is performed using a plasma generated by the O₂ gas. Then, the deposition step (S203), the first removing step (S204), and the second removing step (S204) are repeated two or more times before the product manufacturing start step S207, which is the plasma processing step.

When the O₂ cleaning step S205 is not performed, the residual fluorine may be taken into the coating film in the subsequent SiCl₄ and O₂ coating step S203, which may cause adverse effects on a particle or the like.

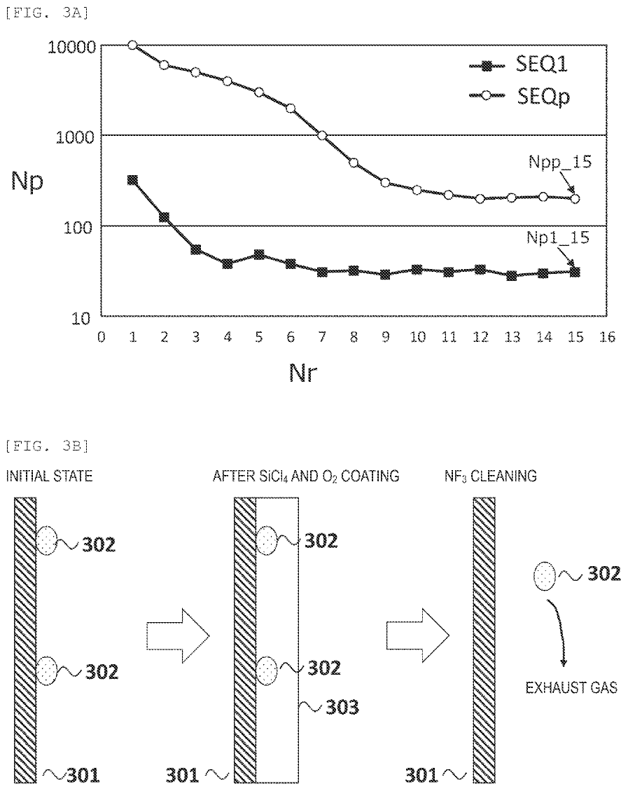

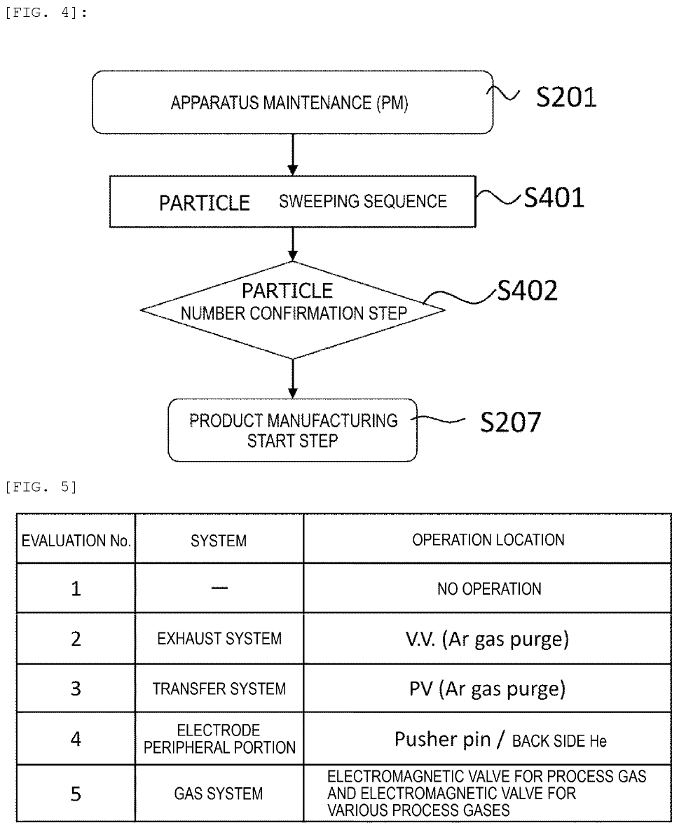

FIG. 3A is a diagram illustrating a relation between the number of times of repetition Nr of the recovery processing S202 and the number of particles Np. FIG. 3A illustrates an example of a result of the processing conditions (SiCl₄ and O₂ coating step S203, NF₃ cleaning step S204, and O₂ cleaning step S205) of the recovery processing S202 illustrated in the first sequence (SEQ1) illustrated in FIG. 2 and a result of a recovery processing of a sequence (SEQp) in a comparative example using Cl₂-base gas. Processing conditions of the recovery processing using the sequence (SEQp) in the comparative example are Cl₂=200 ccm, a pressure of 1 Pa, a microwave power of 800 w, and 90 seconds. Therefore, a processing time under a recovery condition in the first sequence (SEQ1) in the present embodiment and a processing time under a recovery condition in the sequence (SEQp) in the comparative example are unified to be the same.

As illustrated in FIG. 3A, in both the first sequence (SEQ1) and the sequence in the comparative example (SEQp), the number of particles Np decreases as the number of times of repetition Nr of the recovery processing increases. However, it was found that there is a difference between the first sequence (SEQ1) and the sequence in the comparative example (SEQp) in a rate of a decrease in the number of particles Np and the number of reached particles when the recovery processing is repeated 15 times (Npp_15>Np1_15). It is considered that a reason why there is a large effect on reducing the number of particles in the first sequence (SEQ1) is that the formation and removal of the coating film on the surface of the inner wall surface of the processing chamber 100 are repeated.

FIG. 3B is a schematic diagram illustrating an estimation mechanism for removing a particle. In an initial state, particles 302 are adsorbed on a surface 301 of the inner wall surface of the processing chamber 100. After the SiCl₄ and O₂ coating step S203, the particles 302 are covered with a SiOₓ-based film 303. In the next NE₃ cleaning step S204, the SiOₓ-based film 303 and the particles 302 are removed. That is, it is presumed that there is a mechanism by which the particles 302 are removed by overcoming an adsorption force (for example, van der Waals force) of the surface 301 of the inner wall surface of the processing chamber 100. As a result, the present inventors found that the particle can be reduced more quickly under the recovery condition illustrated in the first sequence (SEQ1) than in a processing method for simulating a product processing. A related mechanism will also be described in the following Embodiment 3.

As described above, by repeating the recovery condition (the SiClₐ and O₂ coating step S203, the NF₃ cleaning step S204, and the O₂ cleaning step S205) illustrated in the first sequence (SEQ1), it is possible to implement the plasma etching apparatus 10 in a state in which the product manufacturing can be started in a short period of time.

### Embodiment 2

Embodiment 2 will be described. First, the present inventors investigated a correspondence relation between a machine operation location in the processing chamber 100 of the plasma etching apparatus 10 illustrated in FIG. 1 and a particle falling onto the wafer 110 placed on the electrode 111.

FIG. 4 is a flowchart illustrating a particle sweeping confirmation sequence according to Embodiment 2. In the particle sweeping confirmation sequence, after the apparatus maintenance S201, a particle sweeping sequence (also referred to as a particle sweeping step) S401 was performed, and thereafter, a particle number confirmation step S402 of confirming the number of particles falling on the wafer 110 by transferring the wafer 110 into the processing chamber 100 was performed. In the particle number confirmation step S402, when the number of particles is equal to or less than a reference value, the product manufacturing start step S207 is performed.

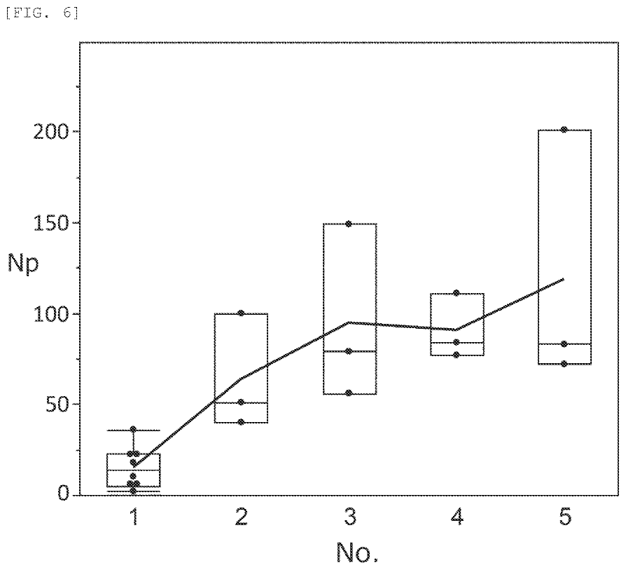

Conditions of the particle number confirmation step S402 were, for example, Ar gas, a microwave power of 800 w, 0.5 Pa, and 30 seconds. FIG. 5 is a table illustrating test contents of the particle sweeping sequence S401 in the particle sweeping confirmation sequence in FIG. 4. There are five evaluation conditions in total. FIG. 5 shows a system of an investigation location for each condition and a specific operation location corresponding thereto.

Evaluation No. 1 is a case of no operation as a reference condition.

In Evaluation No. 2, as an operation of an exhaust system, an operation of switching the vacuum exhaust valve (V.V.) 171 between 5% and 100% while flowing 500 cc of Ar gas (for example, the electromagnetic valve 135 for a process gas and the electromagnetic valve 136 for various process gases are opened for Ar) was performed 20 times.

In Evaluation No. 3, as an operation of a wafer transfer system, an operation of opening and closing the process valve (PV) 120 while flowing 500 cc of the Ar gas (for example, the electromagnetic valve 135 for the process gas and the electromagnetic valve 136 for various process gases are opened for Ar) was performed 20 times.

In Evaluation No. 4, as an operation of a peripheral portion of the electrode 111, an operation of raising and lowering the pusher pin 150 and an operation of opening and closing the electromagnetic valve 131 for backside He gas were performed 20 times while flowing backside He gas 130.

In Evaluation No. 5, as a gas system operation, for all gases (Gas 1, . . . and Gas 20) connected to the plasma etching apparatus 10, an operation of opening and closing the electromagnetic valve 135 for various process gases and an operation of opening and closing the electromagnetic valve 136 for a process gas before being introduced into the processing chamber 100 were performed 20 times.

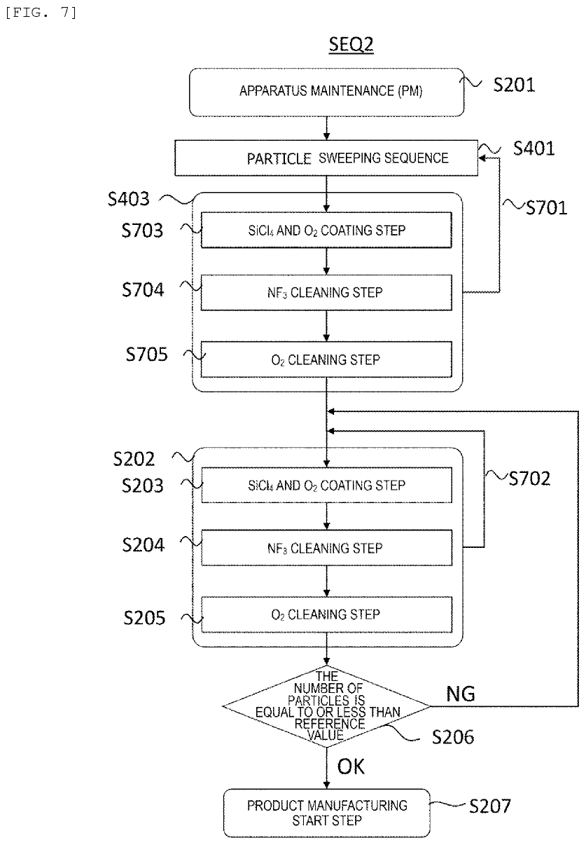

FIG. 6 is an evaluation result diagram illustrating correspondence between an evaluation No. of the particle sweeping sequence and the number of particles (Np). In addition, in order to improve reliability, three or more particle measurement points were acquired. As a result, the number of particles was the minimum in Evaluation No. 1 which is the reference condition without a mechanical operation, and the number of particles Np was increased in all of Evaluation Nos. 2 to 5. From the result, it was found that after the maintenance S201, particle sources are present in all of the exhaust system, the transfer system, the electrode peripheral portion, and the gas system, and it is necessary to previously sweep out and remove the particle.

That is, a process for discharging a particle in the particle sweeping sequence S401 is an operation including one or more of the following operations 1 to 4. Preferably, the operation includes all of the following operations 1 to 4 from the viewpoint of sweeping out and removing the particle.
1: (see Evaluation No. 5) An operation of opening and closing the electromagnetic valves 135 and 136 that control flow of gas flowing from process gas supply units (Gas1, . . . , and Gas20) into the processing chamber 100, and an operation of changing, by the electromagnetic valve 136, a flow rate of the gas supplied by the process gas supply units.
2: (see Evaluation No. 3) An operation of opening and closing the process valve (PV) 120 serving as the inlet and outlet used for transferring the wafer between the processing chamber 100 and the transfer unit (that is, an operation of opening and closing the valve 120 for carrying the sample 110 into and out of the processing chamber 100), and (see Evaluation No. 4) an operation of raising and lowering the pusher pin 150 of the electrode 111 (that is, an operation of raising and lowering the holding member 150 that holds the sample 110 on the sample stage 111).
3: (see Evaluation No. 4) An operation of changing a gas flow rate of the backside He gas 130 by the electromagnetic valve 131 in a He line as an electrode coolant (operation of changing a flow rate of a heat transfer gas 130 for controlling a temperature of the sample 110), and an operation of opening and closing the electromagnetic valve 131 for changing the gas flow rate in the He line (operation of opening and closing the electromagnetic valve 131 that controls flow of the heat transfer gas 130).
4: (see Evaluation No. 2) An operation of the exhaust valve 171 (that is, operation of opening and closing a valve for exhausting the processing chamber 100).

Based on the above results, the present inventors considered that there is a possibility that a combination processing (recovery processing S202) of new recovery conditions (SiCl₄ and O₂ coating step S203, NF₃ cleaning step S204, and O₂ cleaning step S205) illustrated in Embodiment 1 in addition to the particle sweeping sequence S401 is optimal as an efficient method for removing a particle. That is, the method for removing a particle immediately after sweeping out the particle is optimal.

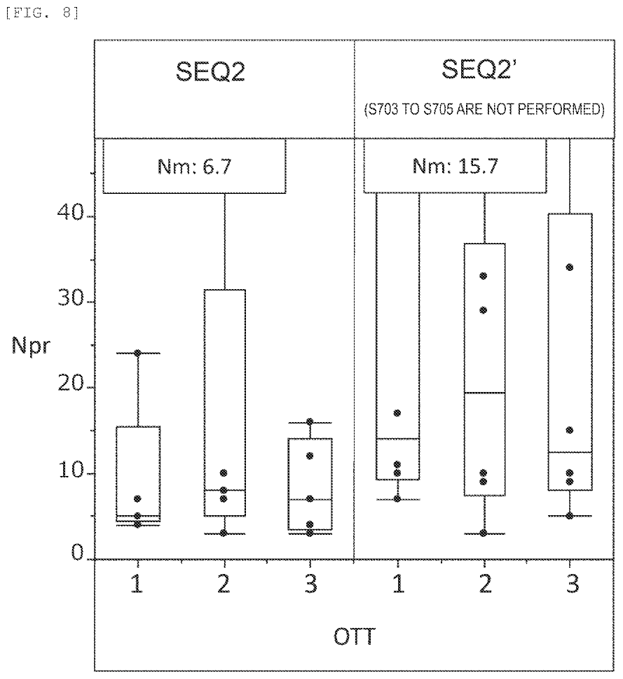

FIG. 7 is a flowchart illustrating a second sequence according to Embodiment 2. The second sequence (SEQ2) can also be referred to as a plasma processing method performed by the plasma etching processing apparatus 10 that performs the product manufacturing start step (S207) after reducing potential particle sources in the processing chamber.

As illustrated in FIG. 7, in the second sequence (SEQ2), the particle sweeping sequence S401 and a recovery processing S403 are newly added after the apparatus maintenance S201 in a flow of the first sequence (SEQ1) in FIG. 2 described in Embodiment 1. The recovery processing S403 has recovery conditions (SiCl₄ and O₂ coating step S703, NF₃ cleaning step S704, and O₂ cleaning step S705) equivalent to the recovery conditions (SiCl₄ and O₂ coating step S203, NF₃ cleaning step S204, and O₂ cleaning step S205) illustrated in Embodiment 1.

In the present embodiment, a step S701 of repeating the particle sweeping sequence S401 and the recovery processing S403 is performed, for example, three times without a wafer (in a state in which the wafer 110 is not placed on the electrode 111 in the processing chamber 100). Thereafter, the number of times of the step S702 of repeating the recovery processing S202 in Embodiment 1 without the particle sweeping sequence S401 is set to, for example, 12 times. Thereafter, it was confirmed whether the number of particles is equal to or less than the reference value in S206. In addition, as the mechanical operation, all operations of Evaluation Nos. 2 to 5 illustrated in FIG. 5 were performed. In the second sequence (SEQ2) in FIG. 7, a condition in which the recovery processing S403 (SiCl₄ and O₂ coating step S703, NFs cleaning step S704, and O₂ cleaning step S705) immediately after the particle sweeping sequence S401 is not performed is defined as a second' sequence (SEQ2′), and the number of particles was confirmed (S206). Using these two sequences (SEQ2 and SEQ2′), in particular, it was investigated whether the recovery processing S403 immediately after the particle sweeping sequence S401 has a particle reduction effect.

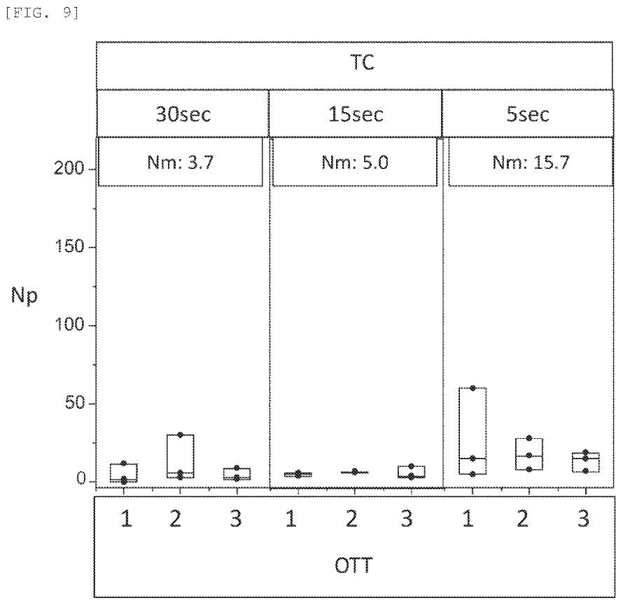

FIG. 8 is a diagram illustrating the number of reached particles (Npr) when processed using the second sequence (SEQ2) and the second' sequence (SEQ2′). In order to improve the reliability, the particles were continuously acquired using three wafers per test (first, second, and third wafers correspond to numerical values of an acquisition opportunity (OTT) illustrated on a horizontal axis in FIG. 8). In addition, tests of the second sequence (SEQ2) and the second' sequence (SEQ2′) were repeated four times or more to improve a result accuracy of the number of particles. Median values (Nm) of all particle data for the second sequence (SEQ2) and the second' sequence (SEQ2′) were 6.7 and 15.7, respectively.

The result means that it is possible to reduce the number of reachable particles by performing the recovery processing S403 immediately after the particle sweeping sequence S401.

In addition, when the result of the first sequence (SEQ1) (FIG. 3A) is reviewed, the number of particles Np was saturated at about 30 when the number of times of the recovery processing S202 is nine or more, and the decrease in the number of particles Np was small.

The results were summarized as follows: “the number of reached particles Npr (=6.7) in the second sequence (SEQ2)<the number of reached particles Npr (=15.7) in the second' sequence (SEQ2′)<the number of reached particles (=about 30) in the first sequence (SEQ1)”.

That is, it was found that the number of reached particles was reduced to 15.7 by adding the particle sweeping sequence S401 to the configuration of the first sequence (SEQ1), and the number of reached particles was further reduced (6.7) by further adding a configuration of repeating the particle sweeping sequence S401 and the recovery processing S403 (SiCl₄ and O₂ coating step S703, NF₃ cleaning step S704, and O₂ cleaning step S705) to the configuration of the first sequence (SEQ1).

As described above, the configuration S701 of repeating the particle sweeping sequence S401 and the recovery processing S403 (SiCl₄ and O₂ coating step S703, NF₃ cleaning step S704, and O₂ cleaning step S705) illustrated in the second sequence (SEQ2) is effective in reducing the number of reached particles, and it is possible to implement the plasma etching apparatus 10 in a state in which the product manufacturing can be started in a short period of time.

A disclosed technique after the apparatus maintenance (PM) S201 is described in the second sequence (SEQ2) of the present embodiment, and can be applied to implementation during a mass production processing. That is, during the mass production processing, the particle sources are accumulating in a machine operation unit. In such a situation, the present disclosure may be applied for the purpose of periodically removing the particle sources. In this case, there is no restriction on performing the apparatus maintenance (PM) S201 in the second sequence (SEQ2), and by performing a flow after the particle sweeping sequence S401 or a part thereof during the mass production processing, it is possible to reduce potential particle risks and stably continue the mass production processing.

An embodiment of the first sequence (SEQ1) and the second sequence (SEQ2) will be additionally described. First, it is desirable to perform the steps (S202, S401, and S402) other than the particle number confirmation step S206 and the product manufacturing start step S207 in a state in which the wafer 110 is not placed on the electrode 111 from the viewpoint of reducing the number of non-product wafers. Next, in the first sequence (SEQ1) and the second sequence (SEQ2), the SiCl₄ and O₂ coating step S703 is used as a step of depositing a coating film on a surface of the processing chamber. In the present embodiment, the processing of step S703 is described using a mixed gas of SiCl₄ gas and O₂ gas as an example, but the use of an alternative gas can be assumed in the formation of the coating film covering the particle. Such an alternative coating film includes a SiO-containing coating film, a CF-containing coating film, a CH-containing coating film, a BO-containing coating film, and a BN-containing coating film. Specific examples of gas for generating the coating film include a mixed gas of SiBr₄ gas and O₂ gas, a mixed gas of SiF₄ gas and O₂ gas, a fluorocarbon gas such as C₄F₃ gas, C₄F₆ gas, CHF₃ gas, CH₃F gas, and CH₂F₂ gas, a mixed gas of BCl₃ gas and O₂ gas, and a mixed gas of BCl₃ gas and N₂ gas.

### Embodiment 3

Embodiment 3 will be described. First, in the present embodiment, in the flow of the second sequence (SEQ2) in FIG. 7 described in Embodiment 2, an influence on the number of particles was investigated by changing a processing time (thickness of a coating film) of the SiCl₄ and O₂ coating step S703. In addition, a time of the NF₃ cleaning step S704 of removing the coating film on a surface of an inner wall of the processing chamber 100 generated in the SiCl₄ and O₂ coating step S703 was three times a time of the coating step S703. That is, a coating time (TC) of the coating step S703 was set to 5 seconds (sec), 15 seconds (sec), and 30 seconds (sec), while the time of the NF₃ cleaning step S704 was set to 15 seconds (sec), 30 seconds (sec), and 45 seconds (sec), respectively.

FIG. 9 is a diagram illustrating a result of the number of particles obtained by acquiring a time dependence of a coating step processing using the second sequence (SEQ2). In order to improve reliability, particles were continuously acquired using three wafers per test (first, second, and third wafers correspond to numerical values of an acquisition opportunity (OTT) illustrated on a horizontal axis in FIG. 9). In addition, the test was repeated three times for each coating time TC to improve a result accuracy of the number of particles Np. The median values Nm of all particle data when the coating time TC was 30 seconds, 15 seconds, and 5 seconds were 3.7, 5.0, and 15.3, respectively. From this result, it is considered that a particle reduction effect is large when the coating time TC is 15 seconds or longer, and the particle reduction effect is small even when the coating time TC is further extended.

It is confirmed by a preliminary inspection that there is a linear relation between the coating step processing time (TC) and a thickness of a SiOₓ coating film formed in the processing chamber 100, and a film of about 17 nm is deposited when the coating step processing time (TC) is 5 seconds. In addition, most of the generated particles have a particle size of 100 nm or less, and it is required to reduce such minute particles. In other words, in order to reduce the number of particles generated with the particle size of 100 nm or less, the particles are promoted to be removed by using a coating film having a film thickness of 50 nm (coating step processing time TC: 15 seconds) or more.

As described above, the first sequence (SEQ1) and the second sequence (SEQ2) using the coating film having a film thickness of 50 nm (coating step processing time TC: 15 seconds) or more are effective for reducing the number of particles with the particle size of 100 nm or less generated in the plasma etching apparatus 10, and it is possible to implement the plasma etching apparatus 10 in a state in which product manufacturing can be started in a short period of time.

The plasma processing methods according to Embodiments 1, 2, and 3 can be summarized as follows.
(1) A plasma processing method for plasma-processing a sample (110) includes: a sweeping step (S401) of sweeping out a particle after apparatus maintenance (S201) of a processing chamber (100) in which the sample (110) is plasma-processed; a deposition step (S703 and S203) of depositing a deposition film in the processing chamber after the sweeping step; a first removing step (S704 and S204) of removing the deposition film after the deposition step; a second removing step (S705 and S205) of removing fluorine in the processing chamber after the first removing step; and a plasma processing step (S207) of plasma-processing the sample placed on a sample stage (111). The sweeping step, the deposition step, the first removing step, and the second removing step are repeated two or more times before the plasma processing step.
(2): In (1), no sample is placed on the sample stage while the sweeping step, the deposition step, the first removing step, and the second removing step are performed.
(3): In (1), operations for discharging a particle in the sweeping step includes the following operations.
1. An operation of opening and closing an electromagnetic valve configured to control flow of gas flowing from a process gas supply unit into the processing chamber,
2. an operation of changing a flow rate of the gas,
3. an operation of opening and closing a valve configured to carry the sample into and out of the processing chamber,
4. an operation of raising and lowering a holding member configured to hold the sample on the sample stage,
5. an operation of changing a flow rate of a heat transfer gas for controlling a temperature of the sample, an operation of opening and closing an electromagnetic valve configured to control flow of the heat transfer gas, or
6. an operation of opening and closing a valve configured to exhaust the processing chamber.
(4) A plasma processing method for plasma-processing a sample (110) includes: a sweeping step (S401) of sweeping out a particle; a deposition step (S203 and S703) of depositing a deposition film in a processing chamber (100) after the sweeping step (S401); a first removing step (S204 and S704) of removing the deposition film after the deposition step; a second removing step (S205 and S705) of removing fluorine in the processing chamber after the first removing step; and a plasma processing step (S207) of plasma-processing the sample placed on a sample stage (111). The sweeping step (S401), the deposition step (S203 and S703), the first removing step (S204 and S704), and the second removing step (S205 and S705) are repeated two or more times before the plasma processing step.
(5) A plasma processing method for plasma-processing a sample (110) includes: a deposition step (S203) of depositing a deposition film in a processing chamber (100) in which the sample is plasma-processed; a first removing step (S204) of removing the deposition film after the deposition step; a second removing step (S205) of removing fluorine in the processing chamber after the first removing step; and a plasma processing step (S207) of plasma-processing the sample (110). The deposition step, the first removing step, and the second removing step are repeated two or more times before the plasma processing step.
(6): In (1), (4), or (5), the deposition step (S203) is performed using a plasma generated by a gas containing a silicon element, the first removing step (S204) is performed using a plasma generated by NF₃ gas, and the second removing step (S205) is performed using a plasma generated by O₂ gas.
(7): In (6), the gas containing the silicon element is SiCl4 gas.
(8): In (1), (4), or (5), the deposition film has a thickness of 50 nm or more.

Although the disclosure made by the present inventors has been specifically described above based on the examples, it is needless to say that the present disclosure is not limited to the above-described embodiments and examples, and various modifications are possible.

### REFERENCE SIGNS LIST

101: quartz shower plate
102: quartz inner tube
103: ground
110: wafer
111: electrode
120: process valve (PV)
130: backside gas supply device
131: electromagnetic valve that controls supply of backside gas
135: electromagnetic valve for a process gas
136: electromagnetic valve for various process gases
140: top plate
142: electromagnet
150: pusher pin
160: radio frequency waveguide that generates plasma
161: RF bias power source
162: matching device
171: vacuum exhaust valve that controls pressure in processing chamber
180: Penning gauge that measures degree of vacuum in processing chamber
181: electromagnetic valve that controls cutout between Penning gauge and chamber
S201: apparatus maintenance (PM)
S203: SiCl₄ and O₂ coating step
S204: NF₃ cleaning step
S205: O₂ cleaning step
S206: measuring number of particles
S207: product manufacturing start step
301: processing chamber surface
302: particles
303: SiOₓ-based film
S401: particle sweeping sequence
S402: measuring number of particles
S403: recovery processing
S701: number of times of repetition of processing including particle sweeping sequence
S702: number of times of repetition of processing
S703: SiCl₄ and O₂ coating step
S704: NF₃ cleaning step
S705: O₂ cleaning step

1. A plasma processing method for plasma-processing a sample, the method comprising:
a sweeping step of sweeping out a particle after maintenance of a processing chamber in which the sample is plasma-processed;
a deposition step of depositing a deposition film in the processing chamber after the sweeping step;
a first removing step of removing the deposition film after the deposition step;
a second removing step of removing fluorine in the processing chamber after the first removing step; and
a plasma processing step of plasma-processing the sample placed on a sample stage, wherein
the sweeping step, the deposition step, the first removing step, and the second removing step are repeated two or more times before the plasma processing step.

2. The plasma processing method according to claim 1, wherein
no sample is placed on the sample stage while the sweeping step, the deposition step, the first removing step, and the second removing step are performed.

3. The plasma processing method according to claim 1, wherein
operations for discharging the particle in the sweeping step includes an operation of opening and closing an electromagnetic valve configured to control flow of gas flowing from a process gas supply unit into the processing chamber, an operation of changing a flow rate of the gas, an operation of opening and closing a valve configured to carry the sample into and out of the processing chamber, an operation of raising and lowering a holding member configured to hold the sample on the sample stage, an operation of changing a flow rate of a heat transfer gas for controlling a temperature of the sample, and an operation of opening and closing an electromagnetic valve configured to control flow of the heat transfer gas or an operation of opening and closing a valve configured to exhaust the processing chamber.

4. A plasma processing method for plasma-processing a sample, the method comprising:
a sweeping step of sweeping out a particle;
a deposition step of depositing a deposition film in a processing chamber after the sweeping step;
a first removing step of removing the deposition film after the deposition step;
a second removing step of removing fluorine in the processing chamber after the first removing step; and
a plasma processing step of plasma-processing the sample placed on a sample stage, wherein
the sweeping step, the deposition step, the first removing step, and the second removing step are repeated two or more times before the plasma processing step.

5. A plasma processing method for plasma-processing a sample, the method comprising:
a deposition step of depositing a deposition film in a processing chamber in which the sample is plasma-processed;
a first removing step of removing the deposition film after the deposition step;
a second removing step of removing fluorine in the processing chamber after the first removing step; and
a plasma processing step of plasma-processing the sample, wherein
the deposition step, the first removing step, and the second removing step are repeated two or more times before the plasma processing step.

6. The plasma processing method according to claim 1, wherein
the deposition step is performed using a plasma generated by a gas containing a silicon element,
the first removing step is performed using a plasma generated by NF₃ gas, and
the second removing step is performed using a plasma generated by O₂ gas.

7. The plasma processing method according to claim 6, wherein the gas containing the silicon element is SiCl₄ gas.

8. The plasma processing method according to claim 1, wherein
the deposition film has a thickness of 50 nm or more.

9. The plasma processing method according to claim 4, wherein
the deposition step is performed using a plasma generated by a gas containing a silicon element,
the first removing step is performed using a plasma generated by NF₃ gas, and
the second removing step is performed using a plasma generated by O₂ gas.

10. The plasma processing method according to claim 9, wherein
the gas containing the silicon element is SiCl₄ gas.

11. The plasma processing method according to claim 4, wherein
the deposition film has a thickness of 50 nm or more.

12. The plasma processing method according to claim 5, wherein
the deposition step is performed using a plasma generated by a gas containing a silicon element,
the first removing step is performed using a plasma generated by NF₃ gas, and
the second removing step is performed using a plasma generated by O₂ gas.

13. The plasma processing method according to claim 12, wherein
the gas containing the silicon element is SiCl₄ gas.

14. The plasma processing method according to claim 5, wherein
the deposition film has a thickness of 50 nm or more.
